(19) United States
(12) Patent Application Publication
(10) Pub. No.: US 2025/0224428 A1
(43) Pub. Date: Jul. 10, 2025

(54) CURRENT SENSOR

(71) Applicant: Murata Manufacturing Co., Ltd., Nagaokakyo-shi (JP)

(72) Inventor: Tatsuki MAEDA, Nagaokakyo-shi (JP)

(21) Appl. No.: 19/089,209

(22) Filed: Mar. 25, 2025

Related U.S. Application Data
(63) Continuation of application No. PCT/JP2023/038479, filed on Oct. 25, 2023.

(30) Foreign Application Priority Data
Nov. 4, 2022 (JP) 2022-177295

(51) Int. Cl. G01R 15/20; G01R 19/00; G01R 33/09

(52) U.S. Cl. CPC G01R 15/207; G01R 19/0092; G01R 33/098

(57) ABSTRACT

First, second and third magnetic detection elements are provided to detect a magnetic field generated by a current flowing through a busbar and are provided at positions different in distance in one direction with respect to the busbar. Each of the magnetic field detection elements detect, in addition to the magnetic field generated from the busbar, a magnetic field generated from each of a plurality of external magnetic field sources other than the busbar. A current detection circuit performs signal processing of performing, based on detection signals of the magnetic fields, a correction for canceling the magnetic field generated from each of the plurality of external magnetic field sources for one of the detection signals of the magnetic field, and outputting the corrected detection signal as a detection signal of the current flowing through the busbar.

### CROSS REFERENCE TO RELATED APPLICATIONS

This application is a continuation of International Application No. PCT/JP2023/038479, filed Oct. 25, 2023, which claims priority to Japanese Patent Application No. 2022-177295, filed Nov. 4, 2022, the contents of each of which are hereby incorporated by reference in their entirety.

### TECHNICAL FIELD

The present disclosure relates to a current sensor.

### BACKGROUND

Japanese Unexamined Patent Application Publication No. 2005-195427 (hereinafter “Patent Document 1”) discloses a configuration of a current measuring device that includes a plurality of magnetic sensors and a signal processing means. The signal processing means calculates a value of a current flowing through a conductor to be measured based on an output signal reflecting difference in current sensitivity of the magnetic sensors.

In the current measuring device described in Patent Document 1, an external magnetic field can be canceled only when a uniform external magnetic field acts on the plurality of magnetic sensors. However, in the current measuring device described in Patent Document 1, when a non-uniform external magnetic field acts on the magnetic sensors, such as when external magnetic fields generated from a plurality of external magnetic field sources act on the magnetic sensors, there is a concern that detection accuracy of the current flowing through the conductor to be measured is reduced.

### SUMMARY OF THE INVENTION

In view of the above-described problem, a current sensor is provided in which detection accuracy of a current flowing through a busbar to be detected is improved even when external magnetic fields generated from a plurality of external magnetic field sources act on a magnetic field detection element.

According to an exemplary aspect of the present disclosure, a current sensor is provided that includes at least three magnetic field detection elements configured to detect a magnetic field generated by a current flowing through a busbar. The sensor includes a current detection circuit configured to output, based on detection signals of a magnetic field outputted from the at least three magnetic field detection elements, a detection signal of the current flowing through the busbar. The at least three magnetic field detection elements are provided at positions different in distance in one direction with respect to the busbar. Each of the magnetic field detection elements are configured to detect, in addition to the magnetic field generated from the busbar, a magnetic field generated from each of a plurality of external magnetic field sources other than the busbar. The current detection circuit is configured to performs signal processing of performing, based on the detection signals of the magnetic field outputted from the at least three magnetic field detection elements, correction for canceling the magnetic field generated from each of the plurality of external magnetic field sources for one of the detection signals of the magnetic field, and outputting the corrected detection signal as the detection signal of the current flowing through the busbar.

According to the exemplary aspects of the present disclosure, even when external magnetic fields generated from a plurality of external magnetic field sources act on a magnetic field detection element, detection accuracy of a current flowing through a busbar to be detected is improved.

### BRIEF DESCRIPTION OF DRAWINGS

FIG. 1 is a perspective view illustrating a configuration of a plurality of current sensors according to Exemplary Embodiment 1.

FIG. 2 is a side view of the plurality of current sensors in FIG. 1 as viewed in an arrow II direction.

FIG. 3 is a perspective view illustrating an inside of a magnetic sensor unit.

FIG. 4 is a layout diagram of a first magnetic detection element, a second magnetic detection element, a third magnetic detection element, and a busbar as viewed in an arrow IV direction in FIG. 3.

FIG. 5 is a layout diagram of the first magnetic detection element, the second magnetic detection element, the third magnetic detection element, and a second busbar as viewed in an arrow V direction in FIG. 3.

FIG. 6 is a diagram illustrating a relationship among the first magnetic detection element, the second magnetic detection element, and the third magnetic detection element, and a first busbar, the second busbar, and a third busbar.

FIG. 7 is a circuit diagram illustrating a configuration of a current detection circuit.

FIG. 8 is a layout diagram of the first magnetic detection element, the second magnetic detection element, the third magnetic detection element, and the second busbar according to Exemplary Embodiment 2.

FIG. 9 is a layout diagram of the first magnetic detection element, the second magnetic detection element, the third magnetic detection element, and the second busbar according to Exemplary Embodiment 2.

FIG. 10 is a circuit diagram illustrating a configuration of an external magnetic field detection circuit for detecting an external magnetic field according to Exemplary Embodiment 3.

FIG. 11 is a diagram illustrating, when a plurality of external magnetic fields that affect a second current sensor according to Exemplary Embodiment 4 include an external magnetic field from the busbar and an external magnetic field from a source other than the busbar, a relationship among the first magnetic detection element, the second magnetic detection element, and the third magnetic detection element, and the busbar, and the external magnetic field from the source other than the busbar.

FIG. 12 is a diagram illustrating an external output state of detection signals of the first magnetic detection element, the second magnetic detection element, and the third magnetic detection element in a test mode according to Exemplary Embodiment 5.

FIG. 13 is a circuit diagram illustrating an example of a gain adjustment circuit configured for adjusting gains of a first amplifier to a seventh amplifier according to Exemplary Embodiment 5.

### DETAILED DESCRIPTION OF EMBODIMENTS

Hereinafter, exemplary embodiments of the present disclosure will be described in detail with reference to the drawings. In the following description, the plurality of embodiments will be described, but it should be appreciated that the configurations described in the exemplary embodiments can be appropriately combined. It is also noted that in the drawings, the same or corresponding parts are denoted by the same reference numerals, and the description thereof will not be repeated.

### Exemplary Embodiment 1

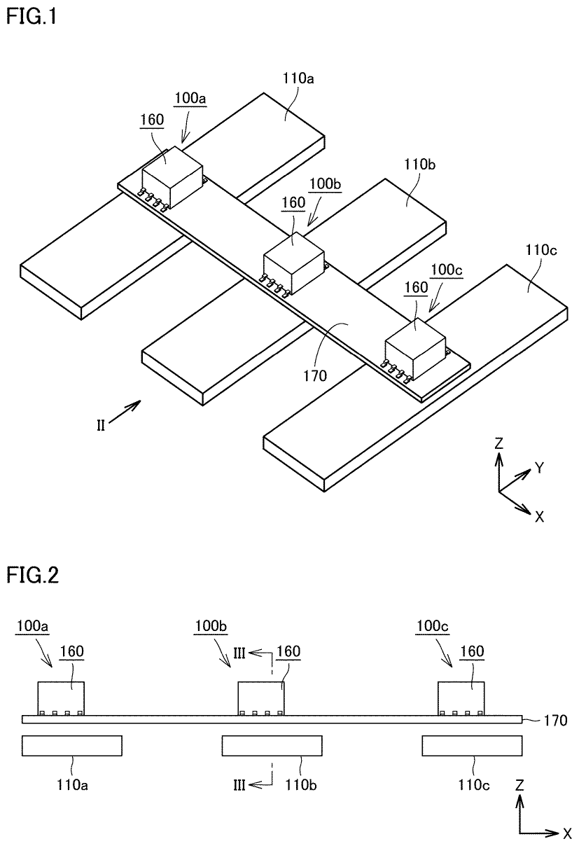

FIG. 1 is a perspective view illustrating a configuration of a plurality of current sensors according to Exemplary Embodiment 1. FIG. 2 is a side view of the plurality of current sensors in FIG. 1 as viewed in an arrow II direction.

Hereinafter, a first current sensor 100a, a second current sensor 100b, and a third current sensor 100c will be described with reference to FIG. 1 and FIG. 2. A plurality of current sensors according to Exemplary Embodiment 1 of the present disclosure include the first current sensor 100a, the second current sensor 100b, and the third current sensor 100c.

As shown, a first busbar 110a, a second busbar 110b, and a third busbar 110c, which are current measurement targets, are disposed at intervals in a first direction (X-axis direction). For example, the first busbar 110a, the second busbar 110b, and the third busbar 110c are three-phase three-wire busbars. A U-phase alternating current flows through the first busbar 110a. A V-phase alternating current flows through the second busbar 110b. A W-phase alternating current flows through the third busbar 110c.

According to an exemplary aspect, the first current sensor 100a, the second current sensor 100b, and the third current sensor 100c are disposed at intervals in the first direction (e.g., the X-axis direction). The first current sensor 100a is provided corresponding to the first busbar 110a in order to detect a current of the first busbar 110a. The second current sensor 100b is provided corresponding to the second busbar 110b in order to detect a current of the second busbar 110b. The third current sensor 100c is provided corresponding to the third busbar 110c in order to detect a current of the third busbar 110c.

The first current sensor 100a is disposed at an interval from the first busbar 110a in a second direction (e.g., the Z-axis direction) orthogonal to the first direction (e.g., the X-axis direction). The second current sensor 100b is disposed at an interval from the second busbar 110b in the second direction (e.g., the Z-axis direction) orthogonal to the first direction (e.g., the X-axis direction). The third current sensor 100c is disposed at an interval from the third busbar 110c in the second direction (e.g., the Z-axis direction) orthogonal to the first direction (e.g., the X-axis direction).

Each of the first current sensor 100a, the second current sensor 100b, and the third current sensor 100c includes a magnetic sensor unit 160. Moreover, a substrate 170 is provided so as to extend in the first direction (e.g., the X-axis direction) at a position away from the first busbar 110a, the second busbar 110b, and the third busbar 110c. The three magnetic sensor units 160 are mounted on the substrate 170.

On the substrate 170, the magnetic sensor unit 160 of the first current sensor 100a is provided at a position facing the first busbar 110a with the substrate 170 interposed therebetween. On the substrate 170, the magnetic sensor unit 160 of the second current sensor 100b is provided at a position facing the second busbar 110b with the substrate 170 interposed therebetween. On the substrate 170, the magnetic sensor unit 160 of the third current sensor 100c is provided at a position facing the third busbar 110c with the substrate 170 interposed therebetween.

It is noted that the three magnetic sensor units 160 are not necessarily mounted on one substrate 170 in an exemplary aspect. Instead, at least one of the three magnetic sensor units 160 may be disposed at a position different from positions of the other magnetic sensor units 160 in the second direction (e.g., the Z-axis direction).

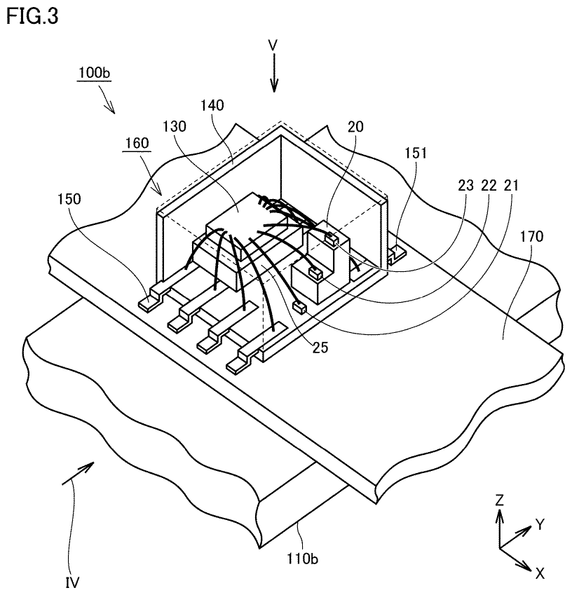

Next, a configuration of an inside of the magnetic sensor unit 160 will be described. FIG. 3 is a perspective view illustrating the inside of the magnetic sensor unit 160. In FIG. 3, as an example, the magnetic sensor unit 160 in the second current sensor 100b is illustrated. A configuration of the magnetic sensor unit 160 in the first current sensor 100a is similar to a configuration of the magnetic sensor unit 160 in the second current sensor 100b and a configuration of the magnetic sensor unit 160 in the third current sensor 100c.

As illustrated in FIG. 3, in the magnetic sensor unit 160, a first magnetic detection element 21, a second magnetic detection element 22, a third magnetic detection element 23, a processing circuit 130, and the like are provided inside the housing 140. The housing 140 is made of a thermoplastic resin such as engineering plastic or a thermosetting resin, such as an epoxy resin or a urethane resin.

As illustrated in FIG. 3, an input terminal 150 and an output terminal 151 are electrically connected to the processing circuit 130 inside the housing 140. The input terminal 150 and the output terminal 151 are extended from inside to outside of the housing 140 and are electrically connected to an electric circuit (not illustrated) provided on the substrate 170. The input terminal 150 is extended in one direction of a third direction (e.g., the Y-axis direction) orthogonal to each of the first direction (e.g., the X-axis direction) and the second direction (e.g., the Z-axis direction), and the output terminal 151 is extended in the other direction of the third direction (e.g., the Y-axis direction).

In the exemplary aspect, the input terminal 150 and the output terminal 151 can be formed of lead frames made of a conductive metal such as copper. When the magnetic sensor unit 160 is formed as a pre-molded package, a base of the housing 140 is integrally molded with the lead frames.

It is noted that the input terminal 150 and the output terminal 151 may be formed of a single printed circuit board. Moreover, a core material of the printed circuit board is formed of a glass epoxy or a thermosetting resin, such as an epoxy resin, a phenol resin, a melamine resin, or a urethane resin.

The first magnetic detection element 21, the second magnetic detection element 22, and the third magnetic detection element 23 are disposed so as to face a busbar to be measured, such as the second busbar 110b, at different distances (heights) in the second direction (e.g., the Z-axis direction). There is a relationship of the first magnetic detection element 21<the second magnetic detection element 22<the third magnetic detection element 23 in terms of distance (height) from the busbar to be measured.

Such a disposition is achieved by providing a stepped member 20 on a bottom surface of the housing 140, disposing the first magnetic detection element 21 on the bottom surface of the housing 140, disposing the second magnetic detection element 22 on a surface of a first step of the stepped member 20, and disposing the third magnetic detection element 23 on a surface of a second step of the stepped member 20. Thus, in the housing 140 of the magnetic sensor unit 160, there is a relationship of the first magnetic detection element 21<the second magnetic detection element 22<the third magnetic detection element 23 in terms of height, and the first magnetic detection element 21 is provided at a lowest position and the third magnetic detection element 23 is provided at a highest position.

The first magnetic detection element 21, the second magnetic detection element 22, and the third magnetic detection element 23 are each fixed in a region where the magnetic detection element is disposed by a die attach film, an insulating adhesive, a conductive adhesive, or the like.

The processing circuit 130 is electrically connected to the first magnetic detection element 21, the second magnetic detection element 22, and the third magnetic detection element 23. In an exemplary aspect, the processing circuit 130 can be configured with an IC chip, such as an ASIC (Application Specific Integrated Circuit). Note that the first magnetic detection element 21, the second magnetic detection element 22, the third magnetic detection element 23, and the processing circuit 130 may be configured with a single IC chip. The processing circuit 130 is fixed on a structure 25 provided on the base of the housing 140 with a die attach film, an insulating adhesive, a conductive adhesive, or the like.

The processing circuit 130 is electrically connected to the input terminal 150 and is supplied with a driving power source. The processing circuit 130 is configured to process detection signals from the first magnetic detection element 21, the second magnetic detection element 22, and the third magnetic detection element 23. The processing circuit 130 is electrically connected to the output terminal 151, and an output signal obtained by processing the above detection signals by the processing circuit 130 is outputted from the output terminal 151.

The first magnetic detection element 21, the second magnetic detection element 22, and the third magnetic detection element 23 are electrically connected to the processing circuit 130 by wire bonding. The input terminal 150 and the output terminal 151 are electrically connected to the processing circuit 130 by wire bonding. In an exemplary aspect, the processing circuit 130 can be electrically connected to the lead frames or the printed circuit board by flip-chip mounting.

The first magnetic detection element 21, the second magnetic detection element 22, the third magnetic detection element 23, and the processing circuit 130 are coated with a coating material such as a silicone resin or an epoxy resin. Note that when the magnetic sensor unit 160 is configured as a transfer mold package, the first magnetic detection element 21, the second magnetic detection element 22, and the third magnetic detection element 23, and the processing circuit 130 are sealed with a mold resin.

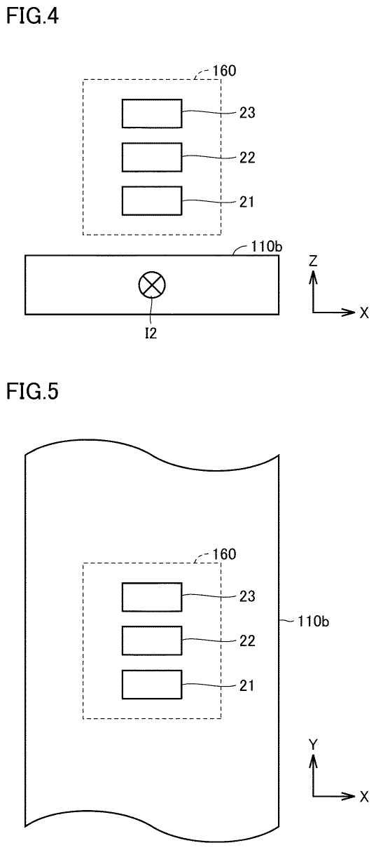

Next, a positional relationship among the first magnetic sensor element 21, the second magnetic sensor element 22, and the third magnetic detection element 23 in the magnetic sensor unit 160, and a positional relationship among the first magnetic sensor element 21, the second magnetic sensor element 22, and the third magnetic detection element 23, and a busbar, such as the second busbar 110b, from which a current is to be detected will be described using FIG. 4 and FIG. 5. In FIG. 4 and FIG. 5, the first magnetic detection element 21, the second magnetic detection element 22, and the third magnetic detection element 23 in the second current sensor 100b are illustrated as an example.

FIG. 4 is a layout diagram of the first magnetic detection element 21, the second magnetic detection element 22, the third magnetic detection element 23, and the second busbar 110b as viewed in the arrow IV direction in FIG. 3. FIG. 5 is a layout diagram of the first magnetic detection element 21, the second magnetic detection element 22, the third magnetic detection element 23, and the second busbar 110b as viewed in the arrow V direction in FIG. 3.

As illustrated in FIG. 4, the first magnetic detection element 21, the second magnetic detection element 22, and the third magnetic detection element 23 are provided side by side in the third direction (e.g., the Y-axis direction) above the second busbar 110b. The first magnetic detection element 21, the second magnetic detection element 22, and the third magnetic detection element 23 overlap a center portion of the second busbar 110b in the first direction (e.g., the X-axis direction).

As illustrated in FIG. 4, the first magnetic detection element 21, the second magnetic detection element 22, and the third magnetic detection element 23 are provided so as to have a relationship of the first magnetic detection element 21<the second magnetic detection element 22<the third magnetic detection element 23 in terms of distance (height) from the second busbar 110b in the second direction (e.g., the Z-axis direction).

The first magnetic detection element 21, the second magnetic detection element 22, and the third magnetic detection element 23 are provided at regular intervals in the second direction (e.g., the Z-axis direction). Note that the intervals among the first magnetic detection element 21, the second magnetic detection element 22, and the third magnetic detection element 23 need not be the regular intervals.

As illustrated in FIG. 5, the first magnetic detection element 21, the second magnetic detection element 22, and the third magnetic detection element 23 are provided at regular intervals in the third direction (e.g., the Y-axis direction). Note that the intervals among the first magnetic detection element 21, the second magnetic detection element 22, and the third magnetic detection element 23 need not be the regular intervals. Further, the first magnetic detection element 21, the second magnetic detection element 22, and the third magnetic detection element 23 only need to be different in position in the second direction (e.g., the Z-axis direction), and may be provided at the same position in the third direction (e.g., the Y-axis direction). Specifically, the first magnetic detection element 21, the second magnetic detection element 22, and the third magnetic detection element 23 may be provided so as to be aligned in the second direction (e.g., the Z-axis direction).

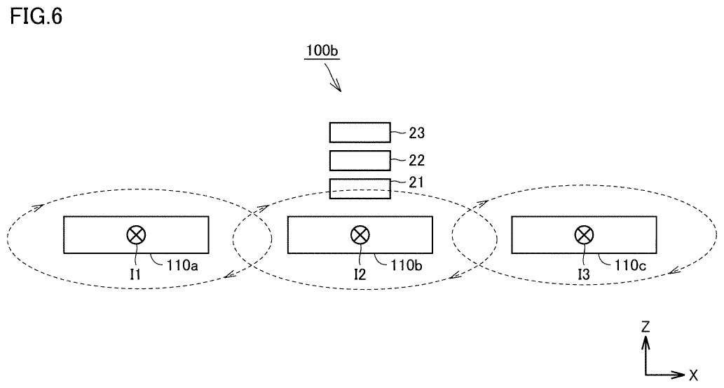

FIG. 6 is a diagram illustrating a relationship among the first magnetic detection element 21, the second magnetic detection element 22, and the third magnetic detection element 23, and the first busbar 110a, the second busbar 110b, and the third busbar 110c. In FIG. 6, the first magnetic detection element 21, the second magnetic detection element 22, and the third magnetic detection element 23 in the second current sensor 100b are illustrated as an example.

A current I1 flowing through (e.g., in) the first busbar 110a, a current I2 flowing through the second busbar 110b, and a current I3 flowing through the third busbar 110c flow in the third direction (e.g., the Y-axis direction). For example, the current I1, the current I2, and the current I3 flow in the respective busbars in one direction of the third direction (e.g., the Y-axis direction).

When a current I1, a current I2, and a current I3 flow, magnetic fields are generated around the first busbar 110a, the second busbar 110b, and the third busbar 110c, as indicated by broken line arrows in the drawing of FIG. 6. In turn. each of the first magnetic detection element 21, the second magnetic detection element 22, and the third magnetic detection element 23 are configured to detect the magnetic fields generated in this way.

The first magnetic detection element 21, the second magnetic detection element 22, and the third magnetic detection element 23 are different in distance from the first busbar 110a, distance from the second busbar 110b, and distance from the third busbar 110c, and thus are configured to output different output values of detection signals when detecting the magnetic fields. For example, since the magnetic detection elements are more likely to be affected by the magnetic field generated from the second busbar 110b (i.e., due to the shorter distance), the output values of the detection signals may differ from each other so as to have a relationship of the first magnetic detection element 21>the second magnetic detection element 22>the third magnetic detection element 23.

### (Configuration of Current Detection Circuit)

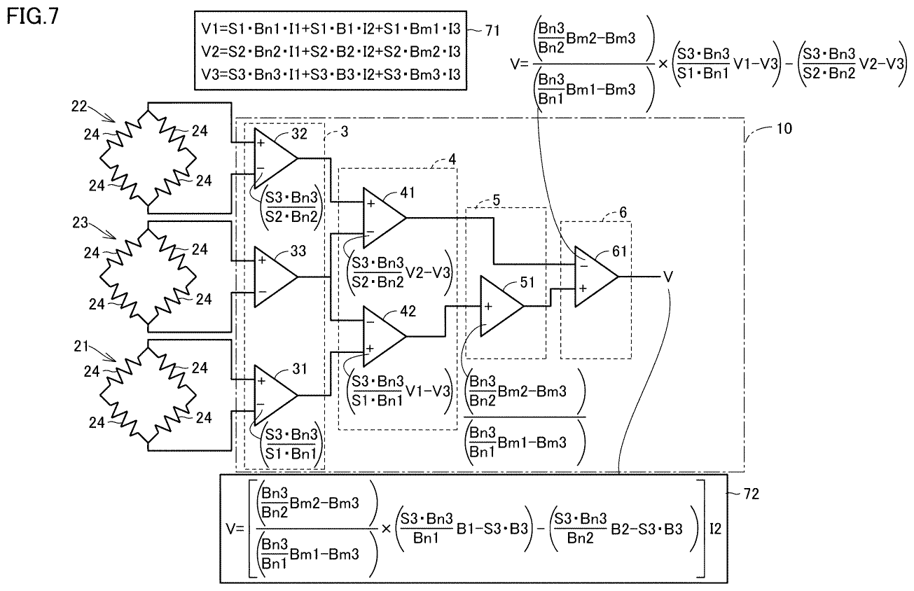

Next, a current detection circuit 10 included in the processing circuit 130 will be described. FIG. 7 is a circuit diagram illustrating a configuration of the current detection circuit 10. In FIG. 7, a configuration of the current detection circuit 10 in the second current sensor 100b is illustrated as an example.

In the exemplary aspect, the current detection circuit 10 is an analog circuit that is configured by connecting circuit elements such as amplifiers, is inputted with detection signals from the first magnetic detection element 21, the second magnetic detection element 22, and the third magnetic detection element 23, and outputs a detection voltage V indicating a current detection value based on the detection signals.

As shown, the current detection circuit 10 includes a first amplifier circuit 3, a second amplifier circuit 4, a third amplifier circuit 5, and a fourth amplifier circuit 6. The first amplifier circuit 3 includes a first amplifier 31, a second amplifier 32, and a third amplifier 33. The second amplifier circuit 4 includes a fourth amplifier 41 and a fifth amplifier 42. The third amplifier circuit 5 includes a sixth amplifier 51. The fourth amplifier circuit 6 includes a seventh amplifier 61. According to the exemplary aspects, the first amplifier 31 to the seventh amplifier 61 can be operational amplifiers configured to perform differential amplification.

In the exemplary aspect, the first magnetic detection element 21 has a bridge circuit of a Wheatstone bridge type including four TMR (Tunnel Magneto Resistance) elements 24. The second magnetic detection element 22 has a bridge circuit having a similar configuration as that of the first magnetic detection element 21. The third magnetic detection element 23 has a bridge circuit having a similar configuration as that of the first magnetic detection element 21.

It is noted that the first magnetic detection element 21, the second magnetic detection element 22, and the third magnetic detection element 23 may have a bridge circuit including a magnetoresistive element such as a GMR (Giant Magneto Resistance) element or an AMR (Anisotropic Magneto Resistance) element instead of the TMR element. Further, the first magnetic detection element 21, the second magnetic detection element 22, and the third magnetic detection element 23 may have a half-bridge circuit including two magnetoresistive elements. Further, the first magnetic detection element 21, the second magnetic detection element 22, and the third magnetic detection element 23 may be a Hall element. Additionally, an IC (integrated circuit) may be incorporated in each of the first magnetic detection element 21, the second magnetic detection element 22, and the third magnetic detection element 23.

Output signals of the first magnetic detection element 21, the second magnetic detection element 22, and the third magnetic detection element 23 pass through the first amplifier circuit 3, the second amplifier circuit 4, the third amplifier circuit 5, and the fourth amplifier circuit 6 in the current detection circuit 10, and are outputted from the current detection circuit 10 as the detection voltage V.

An input/output configuration in the first amplifier circuit 3 is as follows. A detection signal of the first magnetic detection element 21 is inputted to the first amplifier 31. A detection signal of the second magnetic detection element 22 is inputted to the second amplifier 32. A detection signal of the third magnetic detection element 23 is inputted to the third amplifier 33. An output signal of the first amplifier 31, an output signal of the second amplifier 32, and an output signal of the third amplifier 33 are inputted to the second amplifier circuit 4.

A voltage V1 (mV) of the detection signal of the first magnetic detection element 21 inputted to the first amplifier 31 is expressed by the following Formula (1). A voltage V2 (mV) of the detection signal of the second magnetic detection element 22 inputted to the second amplifier 32 is expressed by the following Formula (2). A voltage V3 (mV) of the detection signal of the third magnetic detection element 23 inputted to the third amplifier 33 is expressed by the following Formula (3).

$$V 1 = S 1 \times Bn 1 \times I 1 + S 1 \times B 1 \times I 2 + S 1 \times Bm 1 \times I 3 \qquad ( 1 )$$

$$V 2 = S 2 \times Bn 2 \times I 1 + S 2 \times B 2 \times I 2 + S 2 \times Bm 2 \times I 3 \qquad ( 2 )$$

$$V 3 = S 3 \times Bn 3 \times I 1 + S 3 \times B 3 \times I 2 + S 3 \times Bm 3 \times I 3 \qquad ( 3 )$$

It is noted that Formula (1) to Formula (3) are illustrated as calculation formulae 71 in FIG. 7 for reference.

In this aspect, the symbols in Formula (1) to Formula (3) indicate the following: S1 indicates a sensitivity (mV/mT) of the first magnetic detection element 21; Bn1 indicates a coefficient (mT/A) for a distance between the first magnetic detection element 21 and a first busbar 101a; I1 indicates a value of a current (A) flowing through the first busbar 101a; B1 indicates a coefficient (mT/A) for a distance between the first magnetic detection element 21 and a second busbar 101b; I2 indicates a value of a current (A) flowing through the second busbar 101b; Bm1 indicates a coefficient (mT/A) for a distance between the first magnetic detection element 21 and a third busbar 101c; and I3 indicates a value of a current (A) flowing through the third busbar 101c.

Moreover, in the exemplary aspects, S2 indicates a sensitivity (mV/mT) of the second magnetic detection element 22; Bn2 indicates a coefficient (mT/A) for a distance between the second magnetic detection element 22 and the first busbar 101a; I2 indicates the value of the current (A) flowing through the second busbar 101b; B2 indicates a coefficient (mT/A) for a distance between the second magnetic detection element 22 and the second busbar 101b; and Bm2 indicates a coefficient (mT/A) for a distance between the second magnetic detection element 22 and the third busbar 101c.

Furthermore, S3 indicates a sensitivity (mV/mT) of the third magnetic detection element 23; Bn3 indicates a coefficient (mT/A) for a distance between the third magnetic detection element 23 and the first busbar 101a; I3 indicates the value of the current (A) flowing through the third busbar 101c; B3 indicates a coefficient (mT/A) for a distance between the third magnetic detection element 23 and the second busbar 101b; and Bm3 indicates a coefficient (mT/A) for a distance between the third magnetic detection element 23 and the third busbar 101c.

According to an exemplary aspect, an input/output configuration in the second amplifier circuit 4 is as follows. The output signal of the second amplifier 32 is inputted to a non-inverting input terminal (+) of the fourth amplifier 41. The output signal of the third amplifier 33 is inputted to an inverting input terminal (−) of the fourth amplifier 41 and an inverting input terminal (−) of the fifth amplifier 42. The output signal of the first amplifier 31 is inputted to a non-inverting input terminal (+) of the fifth amplifier 42. An output signal of the fourth amplifier 41 and an output signal of the fifth amplifier 42 are inputted to the third amplifier circuit 5.

Moreover, an input/output configuration in the third amplifier circuit 5 is as follows. The output signal of the fourth amplifier 41 passes through the third amplifier circuit 5 and is inputted to the fourth amplifier circuit 6. The output signal of the fifth amplifier 42 is inputted to a non-inverting input terminal (+) of the sixth amplifier 51. An inverting input terminal (−) of the sixth amplifier 51 is grounded, although not illustrated. An output signal of the sixth amplifier 51 is inputted to the fourth amplifier circuit 6.

Furthermore, an input/output configuration in the fourth amplifier circuit 6 is as follows. The output signal of the fourth amplifier 41 is inputted to an inverting input terminal (−) of the seventh amplifier 61. The output signal of the sixth amplifier 51 is inputted to a non-inverting input terminal (+) of the seventh amplifier 61. The output signal of the sixth amplifier 51 is outputted from the current detection circuit 10 as the detection voltage V indicating a current detection value.

### (Gain Setting Values and Calculation Contents in Current Detection Circuit 10)

Next, with reference to FIG. 7, setting values of gains and calculation contents for the first amplifier 31 to the seventh amplifier 61 in the current detection circuit 10 will be described. In the first amplifier 31 to the seventh amplifier 61, gains are set for the purpose of removing, from the voltage V2 expressed by Formula (2), a component of a voltage value (S2×Bn2×I1) due to an external magnetic field from the first busbar 101a and a component of a voltage value (S2×Bm2× I3) due to an external magnetic field from the third busbar 101c.

A gain (S3×Bn3/S2×Bn2) is set to the second amplifier 32 for removing the component of the voltage value (S2×Bn2×I1) due to the external magnetic field from the first busbar 101a as illustrated in FIG. 7 from the voltage V2 expressed by Formula (2). A gain (S3×Bn3/S1×Bn1) is set to the first amplifier 31 for removing a component of a voltage value (S1×Bn1×I1) due to the external magnetic field from the first busbar 101a from the voltage V1 expressed by Formula (1). A gain (1) is set to the third amplifier 33.

In the fourth amplifier 41, the voltage value V3 of the output signal of the third amplifier 33 is subtracted from a voltage value (S3×Bn3/S2×Bn2)×V2 of the output signal of the second amplifier 32 as illustrated in FIG. 7, and a voltage value [(S3×Bn3/S2×Bn2)×V2−V3] indicating a result of the subtraction is outputted. Thus, the component of the voltage value (S2×Bn2×I1) due to the external magnetic field from the first busbar 101a from the voltage V2 expressed by Formula (2) can be removed.

In the fifth amplifier 42, the voltage value V3 of the output signal of the third amplifier 33 is subtracted from a voltage value (S3×Bn3/S1×Bn1)×V1 of the output signal of the first amplifier 31 as illustrated in FIG. 7, and a voltage value [(S3×Bn3/S1×Bn1)×V1−V3] indicating a result of the subtraction is outputted. Thus, the component of the voltage value (S1×Bn1×I1) due to the external magnetic field from the first busbar 101a from the voltage V1 expressed by Formula (1) can be removed.

In the sixth amplifier 51, a gain [(Bn3/Bn2)×Bm2−Bm3]/[(Bn3/Bn1)×Bm1−Bm3)] is set for removing a component of a voltage value (S2×Bm2×I3) due to the external magnetic field from the third busbar 101c as illustrated in FIG. 7 from the voltage V2 expressed by Formula (2).

In the seventh amplifier 61, a voltage value [(S3×Bn3/S2×Bn2)×V2−V3] of the output signal of the fourth amplifier 41 as illustrated in FIG. 7 is subtracted from a voltage value [(Bn3/Bn2)×Bm2−Bm3]/[Bn3/Bn1)×Bm1−Bm3)]×[(S3×Bn3/S1×Bn1)×V1−V3] of the output signal of the sixth amplifier 51 as illustrated in FIG. 7. Thus, the component of the voltage value (S2×Bm2×I3) due to the external magnetic field from the third busbar 101c from the voltage V2 expressed by Formula (2) can be removed.

When the voltage value V indicating the subtraction result in the seventh amplifier 61 is arranged, V={[(Bn3/Bn2)×Bm2−Bm3]/[(Bn3/Bn1)×Bm1−Bm3)]×[(S3×Bn3×B1/Bn1)−S3×B3]−[(S3×Bn3×B2/Bn2)−S3×B3]}×I2 is obtained as illustrated as a detected voltage formula 72 in FIG. 7. The voltage value V calculated by the seventh amplifier 61 in this way is outputted from the current detection circuit 10 as the detection voltage V indicating the current detection value by the current detection circuit 10.

As described above, in the current detection circuit 10, the component of the voltage value due to the external magnetic field from the first busbar 101a and the component of the voltage value due to the external magnetic field from the third busbar 101c are removed from the voltage V2, based on the voltage V1 indicating the current detected by the first magnetic detection element 21, the voltage V2 indicating the current detected by the second magnetic detection element 22, and the voltage V3 indicating the current detected by the third magnetic detection element 23. Thus, in the current detection circuit 10, correction can be performed, for the voltage V2 of the detection signal indicating the current value I2 of the second busbar 101b detected by the second magnetic detection element 22, for canceling the external magnetic field from the first busbar 101a and the external magnetic field from the third busbar 101c. As a result, the current detection circuit 10 can be configured to output the detection voltage V indicating the current value of the second busbar 101b obtained by canceling the external magnetic field from the first busbar 101a and the external magnetic field from the third busbar 101c.

In this way, the detection voltage V obtained by canceling the plurality of external magnetic fields in the voltage V2 is outputted from the current detection circuit 10 as a voltage value indicating the current value I2 of the second busbar 101b detected by the current detection circuit 10. Thus, in Exemplary Embodiment 1, even when the external magnetic fields generated from the plurality of external magnetic field sources, such as the first busbar 101a and the third busbar 101c, act on the first magnetic detection element 21 to the third magnetic detection element 23 in the current sensor such as the second current sensor 100b, detection accuracy of the current flowing through the busbar to be detected is improved.

Specifically, in Exemplary Embodiment 1, even when there are a plurality of busbars disposed adjacent to a busbar to be detected by a current sensor, the detection value of a current obtained by canceling the action of external magnetic fields generated from the plurality of adjacently disposed busbars can be obtained, and thus, the current sensor is prevented from being affected by the external magnetic fields generated from the plurality of adjacently disposed busbars. Thus, even when there is the plurality of busbars disposed adjacent to the busbar to be detected by the current sensor, the detection accuracy of the current flowing through the busbar being the detection target is improved.

In addition, in Exemplary Embodiment 1, even when there are the plurality of busbars disposed adjacent to the busbar to be detected by the current sensor, the current sensor can be prevented from being affected by the external magnetic fields generated from the plurality of adjacently disposed busbars, and thus a degree of freedom in disposition of the busbars is improved.

In addition, in Exemplary Embodiment 1, even when there are the plurality of busbars disposed adjacent to the busbar to be detected by the current sensor, the current sensor is no affected by the external magnetic fields generated from the plurality of adjacently disposed busbars, and thus there is no need to provide a shield to block the external magnetic fields in the current sensor. Accordingly, manufacturing costs of the current sensor are also reduced.

In addition, in Exemplary Embodiment 1, the current detection circuit 10 is configured with the analog circuit including the first amplifier 31 to the seventh amplifier 61. Thus, when processing related to the current detection including the correction for canceling the plurality of external magnetic fields is performed, a speed of the processing is increased as compared with a case where the processing is performed by digital processing.

It is noted that in Exemplary Embodiment 1, as an example of the current detection circuit 10, the example is illustrated in which the current of the second busbar 101b is detected. The current detection circuit of the first current sensor 100a that detects the current of the first busbar 101a and the current detection circuit of the third current sensor 100c that detects the current of the third busbar 101c can be configured as a circuit that performs processing related to current detection including performing a correction for canceling a plurality of external magnetic fields, based on a similar technical concept to that for the current detection circuit 10 that detects the current of the second busbar 101b.

In addition, in Exemplary Embodiment 1, as an example of the current detection circuit 10, the example is illustrated in which the current detection circuit 10 is configured such that the circuit elements of the first amplifier 31 to the seventh amplifier 61 are configured to perform the processing related to the current detection including the correction for canceling the plurality of external magnetic fields. However, it should be appreciated that the configuration is not limited thereto, and, as for the current detection circuit, a configuration of a circuit element other than the configuration illustrated in FIG. 7 may be adopted as long as the processing related to the current detection including the correction for canceling the plurality of external magnetic fields can be performed.

### Exemplary Embodiment 2

Next, Exemplary Embodiment 2 will be described. As Exemplary Embodiment 2, another layout example of the first magnetic detection element 21, the second magnetic detection element 22, and the third magnetic detection element 23 will be described.

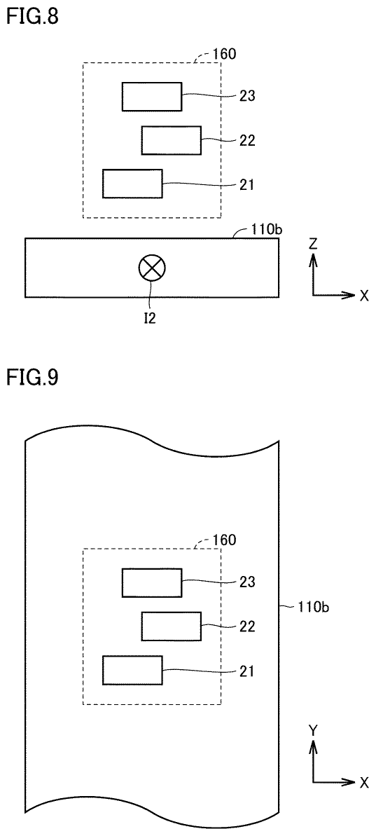

FIG. 8 and FIG. 9 are layout diagrams of the first magnetic detection element 21, the second magnetic detection element 22, the third magnetic detection element 23, and the second busbar 110b according to Exemplary Embodiment 2. FIG. 8 is the layout diagram as viewed in a similar direction to that in FIG. 4. FIG. 9 is the layout diagram as viewed in a similar direction to that in FIG. 5.

As illustrated in FIG. 8 and FIG. 9, the first magnetic detection element 21, the second magnetic detection element 22, and the third magnetic detection element 23 are provided so as to have a relationship of the first magnetic detection element 21<the second magnetic detection element 22<the third magnetic detection element 23 in terms of distance (height) from the second busbar 110b in the second direction (e.g., the Z-axis direction), as in the example in FIG. 4 and FIG. 5, but are not in a layout state of being aligned in the third direction (e.g., the Y-axis direction) as in the example in FIG. 4 and FIG. 5.

As illustrated in FIG. 8 and FIG. 9, the first magnetic detection element 21, the second magnetic detection element 22, and the third magnetic detection element 23 are at least different in distance (height) from the second busbar 110b according to the exemplary aspect.

As illustrated in FIG. 8 and FIG. 9, as long as the first magnetic detection element 21, the second magnetic detection element 22, and the third magnetic detection element 23 are in the layout state of being at least different in distance (height) from the second busbar 110b, correction for canceling the external magnetic field from the first busbar 101a and the external magnetic field from the third busbar 101c can be performed for the voltage V2 of the detection signal indicating the current detected by the second magnetic detection element 22, as in Exemplary Embodiment 1, in the current detection circuit 10. Thus, in the configuration of Exemplary Embodiment 2, a similar effect as that obtained in the configuration of Exemplary Embodiment 1 can be obtained.

Further, it is sufficient that the first magnetic detection element 21, the second magnetic detection element 22, and the third magnetic detection element 23 are in the layout state of being at least different in distance (height) from the second busbar 110b, and thus, a degree of freedom in the disposition of the plurality of magnetic detection elements is improved. In this way, since the degree of freedom in the disposition of the plurality of magnetic detection elements is improved, a robust property is provided against installation errors among the magnetic detection elements and installation errors of the magnetic detection elements with respect to the busbar, and thus it is possible to improve ease of manufacturing in manufacturing processes.

### Exemplary Embodiment 3

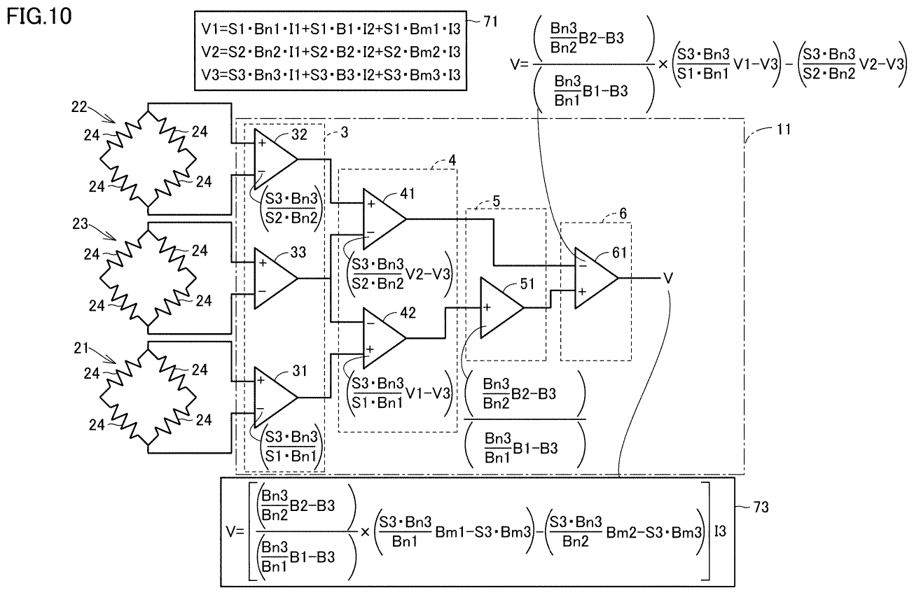

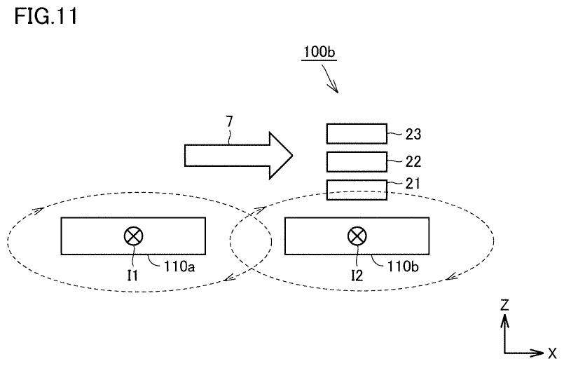

Next, Exemplary Embodiment 3 will be described. In Exemplary Embodiment 3, an external magnetic field detection circuit 11 for detecting an external magnetic field will be described. FIG. 10 is a circuit diagram illustrating a configuration of the external magnetic field detection circuit 11 for detecting an external magnetic field according to Exemplary Embodiment 3. In FIG. 10, the configuration of the external magnetic field detection circuit 11 in the second current sensor 100b is illustrated as an example. The external magnetic field detection circuit 11 is included in the processing circuit 130 together with the current detection circuit 10 described above.

The external magnetic field detection circuit 11 includes the first amplifier 31 to the seventh amplifier 61 connected to have a similar connection relationship as that in the current detection circuit 10. Gains are set in the first amplifier 31 to the seventh amplifier 61, for the purpose of removing the component of the voltage value (S2×Bn2×I1) due to the external magnetic field from the first busbar 101a and a component of a voltage value (S2×B2×I2) due to the magnetic field from the second busbar 101b from the voltage V2 expressed by Formula (2) and obtaining the component of the voltage value (S2×Bm3×I3) due to the external magnetic field from the third busbar 101c as a value of the external magnetic field.

Differences of the external magnetic field detection circuit 11 from the current detection circuit 10 are the gain set in the sixth amplifier 51 and calculation contents in the seventh amplifier 61.

A configuration and the gains of the first amplifier 31 to the fifth amplifier 42 are similar to the configuration and the gains of the first amplifier 31 to the fifth amplifier 42 illustrated in FIG. 7, and thus in the fourth amplifier 41, as described above, the component of the voltage value (S2×Bn2×I1) due to the external magnetic field from the first busbar 101a from the voltage V2 expressed by Formula (2) can be removed.

In the sixth amplifier 51, a gain [(Bn3/Bn2)×B2−B3]/[(Bn3/Bn1)×B1−B3)] is set for removing the component of the voltage value (S2×B2× I2) due to the magnetic field from the second busbar 101b from the voltage V2 expressed by Formula (2).

In the seventh amplifier 61, the voltage value [(S3× Bn3/S2×Bn2)×V2−V3] of the output signal of the fourth amplifier 41 as illustrated in FIG. 10 is subtracted from a voltage value [(Bn3/Bn2)×B2−B3]/[(Bn3/Bn1)×B1−B3)]×[(S3×Bn3/S1×Bn1)×V1−V3] of the output signal of the sixth amplifier 51 as illustrated in FIG. 10. Thus, the component of the voltage value (S2×B2×I2) due to the magnetic field from the second busbar 101b is removed from the voltage V2 expressed by Formula (2).

When the voltage value V indicating the subtraction result in the seventh amplifier 61 is arranged, V={[(Bn3/Bn2)×B2−B3]/[(Bn3/Bn1)×B1−B3)]×[(S3×Bn3×Bm1/Bn1)−S3×Bm3]−[(S3×Bn3×Bm2/Bn2)−S3×Bm3]}×I3 is obtained as illustrated in a detected voltage formula 73 in FIG. 10. The voltage value V calculated by the seventh amplifier 61 in this way is outputted from the external magnetic field detection circuit 11 as the detection voltage V indicating a detection value of the external magnetic field from the third busbar 101c by the external magnetic field detection circuit 11.

As described above, in the external magnetic field detection circuit 11, the component of the voltage value due to the external magnetic field from the first busbar 101a and the component of the voltage value due to the magnetic field from the second busbar 101b are removed from the voltage V2, based on the voltage V1 indicating the current detected by the first magnetic detection element 21, the voltage V2 indicating the current detected by the second magnetic detection element 22, and the voltage V3 indicating the current detected by the third magnetic detection element 23. Thus, in the external magnetic field detection circuit 11, for the voltage V2 of the detection signal indicating the current value detected by the second magnetic detection element 22, correction for canceling the external magnetic field from the first busbar 101a and the magnetic field from the second busbar 101b can be performed.

In this way, the voltage V obtained by canceling the external magnetic field from the first busbar 101a and the magnetic field from the second busbar 101b from the voltage V2 is outputted from the external magnetic field detection circuit 11 as the detection voltage V due to the external magnetic field from the third busbar 101c. Thus, in Exemplary Embodiment 3, when the external magnetic fields generated from the plurality of external magnetic field sources act on the first magnetic detection element 21 to the third magnetic detection element 23, the external magnetic field can be detected.

In Exemplary Embodiment 3, the example is illustrated in which the external magnetic field from the third busbar 101c is detected as an example of the external magnetic field detection circuit 11. The external magnetic field detection circuit that detects the external magnetic field from the first busbar 101a can be configured by a similar technical concept as that for the external magnetic field detection circuit 11 that detects the external magnetic field from the third busbar 101c. For example, by configuring an external magnetic field detection circuit such that the voltage V obtained by canceling the external magnetic field from the third busbar 101c and the magnetic field from the second busbar 101b from the voltage V2 is outputted as the detection voltage V due to the external magnetic field from the first busbar 101a, the external magnetic field from the first busbar 101a can be detected.

When the external magnetic field can be detected by the external magnetic field detection circuit 11 as in Exemplary Embodiment 3, magnitude of the external magnetic field can be checked in a system in which the current sensor is installed, and thus, it is also possible to detect whether or not an abnormal state occurs in an entirety of the system.

It is noted that in Exemplary Embodiment 3, as an example of the external magnetic field detection circuit 11, the example is illustrated in which the external magnetic field detection circuit 11 is configured such that the circuit elements of the first amplifier 31 to the seventh amplifier 61 are used to perform the processing of detecting the external magnetic field. However, the configuration is not limited thereto, and as for the external magnetic field detection circuit, a configuration of a circuit element other than the configuration illustrated in FIG. 10 may be adopted as long as the processing relating to the current detection including the correction for canceling the magnetic field from the busbar being the detection target, and the external magnetic field from the busbar other than the detection target can be performed.

### Exemplary Embodiment 4

Next, Exemplary Embodiment 4 will be described. In Exemplary Embodiment 4, an example of a current detection circuit and an example of an external magnetic field detection circuit will be described for a case where a plurality of external magnetic fields include the external magnetic field from the first busbar 101a and an external magnetic field from a source other than the busbar such as the geomagnetism which is a parallel magnetic field.

FIG. 11 is a diagram illustrating, when a plurality of external magnetic fields that affect the second current sensor 100b according to Exemplary Embodiment 4 include the external magnetic field from the first busbar 101a and an external magnetic field from a source other than the busbar, a relationship among the first magnetic detection element 21, the second magnetic detection element 22, and the third magnetic detection element 23, and the first busbar 110a, and an external magnetic field 7 from a source other than the busbar.

Referring to FIG. 11, the plurality of external magnetic fields that affect the second current sensor 100b may include the external magnetic field from the first busbar 101a and the external magnetic field 7 from the source other than the busbar. In such a case, the voltage V1 (mV) of the detection signal of the first magnetic detection element 21 is expressed by the following Formula (4). Moreover, the voltage V2 (mV) of the detection signal of the second magnetic detection element 22 is expressed by the following Formula (5). Further, the voltage V3 (mV) of the detection signal of the third magnetic detection element 23 is expressed by the following formula (6).

$$V 1 = S 1 \times Bn 1 \times I 1 + S 1 \times B 1 \times I 2 + S 1 \times Bm \qquad ( 4 )$$

$$V 2 = S 2 \times Bn 2 \times I 1 + S 2 \times B 2 \times I 2 + S 2 \times Bm \qquad ( 5 )$$

$$V 3 = S 3 \times Bn 3 \times I 1 + S 3 \times B 3 \times I 2 + S 3 \times Bm \qquad ( 6 )$$

In the above Formula (4), Formula (5) and Formula (6), Bm indicates a uniform external magnetic field (mT) such as the geomagnetism. It is noted that the description of common matters between Formula (4), Formula (5) and Formula (6) and Formula (1), Formula (2) and Formula (3) described above will not be repeated.

As illustrated in FIG. 11, when the external magnetic field from the first busbar 101a and the external magnetic field 7 from the source other than the busbar are included as the plurality of external magnetic fields affecting the second current sensor 100b, the component of the external magnetic field from the third busbar 101c can be replaced with a component of the external magnetic field 7 from the source other than the busbar in the above Formula (1), Formula (2) and Formula (3) as expressed by the above Formula (4), Formula (5) and Formula (6).

Thus, when the external magnetic field from the first busbar 101a and the external magnetic field 7 from the source other than the busbar are included as the plurality of external magnetic fields affecting the second current sensor 100b, a current detection circuit that outputs the detection voltage V obtained by performing correction for canceling the component of the external magnetic field from the first busbar 101a and correction for canceling the component of the external magnetic field 7 from the source other than the busbar in Formula (5) can be configured based on a similar technical concept to that for the current detection circuit 10 in FIG. 7. By using such a current detection circuit, even when the external magnetic fields generated from the plurality of external magnetic field sources including the external magnetic field 7 from the source other than the busbar act on the first magnetic detection element 21 to the third magnetic detection element 23, detection accuracy of the current flowing through the busbar to be detected is improved.

Further, when the external magnetic field from the first busbar 101a and the external magnetic field 7 from the source other than the busbar are included as the plurality of external magnetic fields affecting the second current sensor 100b, an external magnetic field detection circuit that detects the external magnetic field can be configured based on a similar technical concept to that for the external magnetic field detection circuit 11 in FIG. 10.

### Exemplary Embodiment 5

Next, Exemplary Embodiment 5 will be described. In Exemplary Embodiment 5, an example will be described in which, after the current sensors such as the first current sensor 100a, the second current sensor 100b, and the third current sensor 100c are mounted, currents are detected by the first magnetic detection element 21, the second magnetic detection element 22, and the third magnetic detection element 23 in the test mode described later, and gains of the amplifiers such as the first amplifier 31 to the seventh amplifier 61 can be adjusted according to detection values of the currents in the test mode.

### (Configuration of Test Mode)

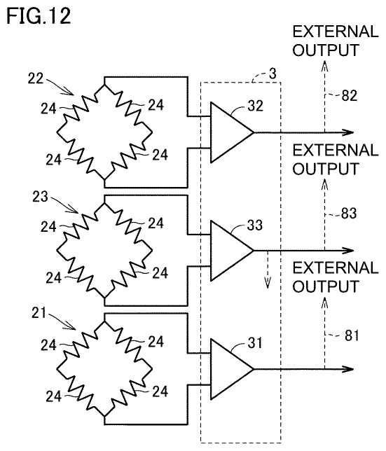

FIG. 12 is a diagram illustrating an external output state of detection signals of the first magnetic detection element 21, the second magnetic detection element 22, and the third magnetic detection element 23 in the test mode according to Exemplary Embodiment 5.

Referring to FIG. 12, an external output path 81 for outputting a detection signal from the above-described first magnetic detection element 21 outward the current sensor, an external output path 82 for outputting a detection signal from the second magnetic detection element 22 outward the current sensor, and an external output path 83 for outputting a detection signal from the third magnetic detection element 23 outward the current sensor are provided. When the test mode is performed, gains of the first magnetic detection element 21, the second magnetic detection element 22, and the third magnetic detection element 23 are set to 1.

The external output path 81 is provided as a path branching off from an output terminal of the first amplifier 31. The external output path 82 is provided as a path branching off from an output terminal of the second amplifier 32. The external output path 83 is provided as a path branching off from an output terminal of the third amplifier 33.

Each of the external output path 81, the external output path 82, and the external output path 83 is provided with a switch or the like for switching an output destination path among signal paths connected to amplifiers at a next stage, and when the test mode is performed, the output destination path is switched by the switch or the like, and an output signal of a corresponding amplifier is supplied. By providing such an external output path 81, an external output path 82, and an external output path 83, the detection signal from the first magnetic detection element 21, the detection signal from the second magnetic detection element 22, and the detection signal from the output terminal of the third amplifier 33 are outputted outward the current sensors, in the test mode.

It is noted that data for the above-described sensitivities S1, S2, and S3, and the coefficients B1, B2, B3, Bn1, Bn2, Bn3, Bm1, Bm2, and Bm3 is set at the time of design. Of the data, the coefficients B1, B2, B3, Bn1, Bn2, Bn3, Bm1, Bm2, and Bm3 are values that vary depending on the distances between the busbars to be detected and the magnetic detection elements, and when the current sensors are installed at an actual installation site, optimum values may be determined at the installation site.

In order to further improve detection accuracy of the voltage V indicating the detection value of the current sensor, it is sufficient that the detection signal from the first magnetic detection element 21, the detection signal from the second magnetic detection element 22, and the detection signal from the output terminal of the third amplifier 33 are obtained outside the current sensor in the test mode at the installation site, the coefficients B1, B2, B3, Bn1, Bn2, Bn3, Bm1, Bm2, and Bm3 corresponding to an installation condition of the current sensor at the site are determined, and gains of the amplifiers such as the first amplifier 31 to the seventh amplifier 61 are adjusted according to a result thereof.

For example, when the gains of the first amplifier 31 to the seventh amplifier 61 are set using Formula (1) to Formula (3), as described below, it is sufficient that optimal coefficients most suitable for reality are determined according to the detection signal from the first magnetic detection element 21, the detection signal from the second magnetic detection element 22, and the detection signal from the output terminal of the third amplifier 33 obtained in the test mode, and the gains of the amplifiers are adjusted according to the coefficients.

According to an exemplary aspect, the coefficients B1, B2, B3, Bn1, Bn2, Bn3, Bm1, Bm2, and Bm3 are determined by, for example, the following procedure. First, the current I1 being constant is caused to flow through only the first busbar 101a. Thus, in Formula (1) to Formula (3), voltages of V1=S1×Bn1×I1, V2=S2×Bn2×I1 and V3=S3×Bn2×I1 are outputted outward. In this case, since the sensitivities S1, S2, and S3, and the current I1 are known, the coefficients B1, B2, and B3 can be determined by calculation from the relational formulae V1=S1×Bn1×I1, V2=S2×Bn2×I1 and V3=S3×Bn2×I1. Similarly, when the current I2 being constant is caused to flow through only the second busbar 101b, the coefficients Bn1, Bn2, and Bn3 can be determined by calculation based on a similar principle. Similarly, when the current I3 being constant is caused to flow through only the third busbar 101c, the coefficients Bm1, Bm2, and Bm3 can be determined by calculation based on a similar principle.

In such a test mode, when the coefficients B1, B2, B3, Bn1, Bn2, Bn3, Bm1, Bm2, and Bm3 corresponding to the actual installation site are determined, adjustment for changing the gains of the first amplifier 31 to the seventh amplifier 61 described above to values reflecting these coefficients needs to be performed.

### (Configuration of Circuit for Adjusting Gains of Amplifiers)

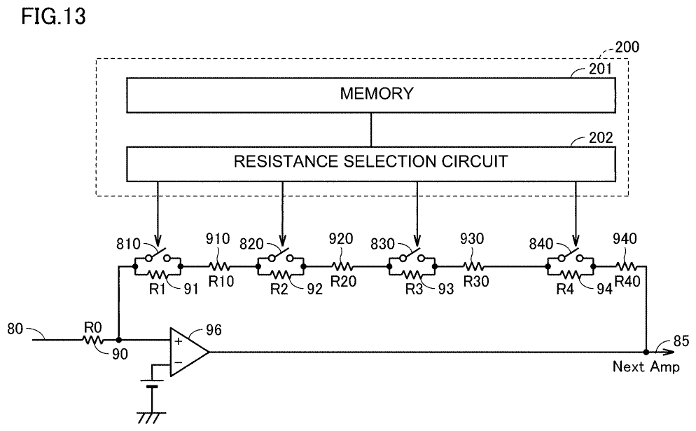

Next, a circuit for adjusting the gains of the first amplifier 31 to the seventh amplifier 61 will be described. FIG. 13 is a circuit diagram illustrating an example of an adjustment circuit 200 configured to adjust a gain of each of the first amplifier 31 to the seventh amplifier 61 according to Exemplary Embodiment 5. The adjustment circuit 200 is a circuit configured to adjust a parameter such as a gain for each of the circuit elements such as the first amplifier 31 to the seventh amplifier 61 in the analog circuit configured with the first amplifier 31 to the seventh amplifier 61.

Referring to FIG. 13, the adjustment circuit 200 includes a memory 201 and a resistance selection circuit 202. The memory 201 is configured to store a value of a gain of an amplifier to be adjusted. The memory 201 is connected to an input device (not illustrated) provided outside a current sensor. A person who adjusts a gain of the amplifier inputs data of a gain after adjustment from the input device. The data of the gain inputted from the input device in this way is stored in the memory 201. The resistance selection circuit 202 is a digital circuit that reads the data of the gain stored in the memory 201, and turns on/off switches 810 to 840 provided in an amplifier 96 to set a gain corresponding to the read data of the gain to the amplifier 96, to adjust a resistance value of a resistor connected to a non-inverting input terminal side of the amplifier 96.

In FIG. 13, the amplifier 96 indicates a representative example of the first amplifier 31 to the seventh amplifier 61. A non-inverting input terminal of the amplifier 96 is supplied with an input signal from an input signal line 80 via a resistor 90 (resistance value R0). An inverting input terminal (−) of the amplifier 96 is grounded, for example. Resistors 91 (resistance value R1), 910 (resistance value R10), 92 (resistance value R2), 920 (resistance value R20), 93 (resistance value R3), 930 (resistance value R30), 94 (resistance value R4) and 940 (resistance value R40) are connected in series between the non-inverting input terminal (+) of the amplifier 96 and an output signal line 85 of the amplifier 96.

The resistor 91 and the switch 810 are connected in parallel between the resistor 90 and the resistor 910. The resistor 92 and the switch 820 are connected in parallel between the resistor 910 and the resistor 920. The resistor 93 and the switch 830 are connected in parallel between the resistor 920 and the resistor 930. The resistor 94 and the switch 840 are connected in parallel between the resistor 930 and the resistor 940.

In such a configuration, when all of the switches 810 to 840 are brought into an ON state, a gain of the amplifier 96 is set to (R10+R20+R30+R40)/R0. Then, by the resistance selection circuit 202 appropriately selecting the ON state/an OFF state of the switches 810 to 840 corresponding to the data of the gain stored in the memory 201, the gain of the amplifier 96 is adjusted to be a gain corresponding to the data of the gain stored in the memory 201. Each of the first amplifier 31 to the seventh amplifier 61 is configured similarly to the amplifier 96 illustrated in FIG. 13, and thus it is possible to individually adjust setting of the gains.

With the configuration as illustrated in FIG. 13, the gains of the first amplifier 31 to the seventh amplifier 61 can be adjustable, and thus, when the coefficients B1, B2, B3, Bn1, Bn2, Bn3, Bm1, Bm2, and Bm3 corresponding to the actual installation site are determined in the test mode, adjustment for changing the gains of the first amplifier 31 to the seventh amplifier 61 to values reflecting these coefficients can be performed.

In this way, in the test mode, the coefficients B1, B2, B3, Bn1, Bn2, Bn3, Bm1, Bm2, and Bm3 corresponding to the actual installation site are determined, and the gains of the first amplifier 31 to the seventh amplifier 61 are adjusted to values reflecting these coefficients, and thus, detection accuracy of the voltage V indicating the detection value of the current sensor can be further improved according to a state of the actual installation site of the current sensor.

Note that in Exemplary Embodiment 5, the example is illustrated in which the plurality of resistors for adjusting the gain of the amplifier 96 are connected in series. However, it is noted that the present disclosure is not limited thereto, and exemplary configurations may be adopted in which the plurality of resistors for adjusting the gain of the amplifier 96 are connected in parallel.

Further, the adjustment of the gain of the amplifier 96 according to Exemplary Embodiment 5 may be used to adjust the gains of the first amplifier 31 to the seventh amplifier 61 included in the external magnetic field detection circuit 11 that detects the external magnetic field according to Exemplary Embodiment 3.

Next, the features of the exemplary embodiments according to the present disclosure will be collectively described.

In a first exemplary aspect <1>, a current sensor is provided that includes at least three magnetic field detection elements (e.g., the first magnetic detection element 21, the second magnetic detection element 22, and the third magnetic detection element 23) configured to detect a magnetic field generated by a current flowing through a busbar (the second busbar 110b), and a current detection circuit (e.g., the current detection circuit 10) configured to output, based on detection signals of a magnetic field outputted from the at least three magnetic field detection elements, a detection signal of the current flowing through or in the busbar. In this aspect, the at least three magnetic field detection elements are provided at positions different in distance in one direction with respect to the busbar. Each of the magnetic field detection elements is also configured to detect a magnetic field generated from each of a plurality of external magnetic field sources (the first busbar 110a and the third busbar 110c, or the external magnetic field 7) other than the busbar. The current detection circuit is configured to process, based on the detection signals of the magnetic field outputted from the at least three magnetic field detection elements, a correction for canceling the magnetic field generated from each of the plurality of external magnetic field sources for one of the detection signals of the magnetic field, and to output the corrected detection signal as the detection signal of the current flowing through the busbar.

In another exemplary aspect <2>, the current sensor according to aspect <1> is provided such that the current detection circuit is configured to determine, based on difference in output of the detection signals of the magnetic field outputted from the at least three magnetic field detection elements, magnitude of the magnetic field generated from each of the plurality of external magnetic field sources, and to perform the correction for canceling the magnetic field generated from each of the plurality of external magnetic field sources by subtracting a value according to the specified magnitude of the magnetic field from a signal value of the one of the detection signals of the magnetic field.

In another exemplary aspect <3>, the current sensor according to either of aspects <1> or <2> is provided such that the current detection circuit is configured to perform the correction for canceling the magnetic field generated from each of the plurality of external magnetic field sources by an analog circuit.

In another exemplary aspect <4>, the current sensor according to aspect <3> further includes an adjustment circuit (e.g., the adjustment circuit 200) configured to adjust parameters (e.g., gains) of circuit elements included in the analog circuit.

In another exemplary aspect <5>, the current sensor according to any one of aspects <1> to <4> is provided such that the at least three magnetic field detection elements include a first magnetic field detection element (e.g., the first magnetic detection element 21), a second magnetic field detection element (e.g., the second magnetic detection element 22) and a third magnetic field detection element (e.g., the third magnetic detection element 23). In this aspect, the current detection circuit includes a first amplifier (e.g., the first amplifier 31) that amplifies a detection signal of the first magnetic field detection element, a second amplifier (e.g., the second amplifier 32) that amplifies a detection signal of the second magnetic field detection element, a third amplifier (e.g., the third amplifier 33) that amplifies a detection signal of the third magnetic field detection element, a fourth amplifier (e.g., the fourth amplifier 41) that amplifies a difference between an output signal of the second amplifier and an output signal of the third amplifier, a fifth amplifier (e.g., the fifth amplifier 42) that amplifies a difference between an output signal of the first amplifier and the output signal of the third amplifier, a sixth amplifier (e.g., the sixth amplifier 51) that amplifies an output signal of the fifth amplifier, and a seventh amplifier (e.g., the seventh amplifier 61) that amplifies a difference between an output signal of the fourth amplifier and an output signal of the sixth amplifier. In this aspect, correction for canceling a magnetic field generated from a first external magnetic field source (e.g., the first busbar 110a) is performed by the first amplifier (e.g., first amplifier 31), the second amplifier (e.g., the second amplifier 32), the third amplifier (e.g., the third amplifier 33), the fourth amplifier (e.g., the fourth amplifier 41), and the fifth amplifier (the fifth amplifier 42), and correction for canceling a magnetic field generated from a second external magnetic field source (e.g., the third busbar 110c or the external magnetic field 7) is performed by the sixth amplifier (e.g., the sixth amplifier 51) and the seventh amplifier (e.g., the seventh amplifier 61).

In another exemplary aspect <6>, the current sensor according to any one of aspects <1> to <5> further includes an external magnetic field detection circuit (e.g., the external magnetic field detection circuit 11) configured to perform, based on the detection signals outputted from the at least three magnetic field detection elements, correction for canceling a magnetic field generated from one of the plurality of external magnetic field sources, and a magnetic field generated from the busbar for the one of the detection signals of the magnetic field, and output the corrected detection signal as a detection signal of a magnetic field generated from another one of the plurality of external magnetic field sources.

In another exemplary aspect <7>, the current sensor according to aspect <6> is configured such that the external magnetic field detection circuit is configured to determiner, based on difference in output of the detection signals of the magnetic field outputted from the at least three magnetic field detection elements, magnitude of the magnetic field generated from the one of the external magnetic field sources and the magnetic field generated from the busbar, and to perform the correction for canceling the magnetic field generated from the one of the external magnetic field sources and the magnetic field generated from the busbar by subtracting values according to the specified magnitude of the magnetic fields from a signal value of the one of the detection signals of the magnetic field.

In another exemplary aspect <8> The current sensor (the second current sensor 100b) according to <7>, wherein the external magnetic field detection circuit (the external magnetic field detection circuit 11) performs the signal processing including the correction for canceling the magnetic field generated from the one of the external magnetic field sources (the first busbar 110a and the third busbar 110c, or the external magnetic field 7) and the magnetic field generated from the busbar (the second busbar 110b) by an analog circuit.

In another exemplary aspect <9>, the current sensor according to aspect <8> further includes an adjustment circuit (e.g., the adjustment circuit 200) configured to adjust parameters (e.g., gains) of circuit elements included in the analog circuit.

### REFERENCE SIGNS LIST

21 FIRST MAGNETIC DETECTION ELEMENT
22 SECOND MAGNETIC DETECTION ELEMENT
23 THIRD MAGNETIC DETECTION ELEMENT
110a FIRST BUSBAR
110b SECOND BUSBAR
110c THIRD BUSBAR
10 CURRENT DETECTION CIRCUIT
100a FIRST CURRENT SENSOR
100b SECOND CURRENT SENSOR
100c THIRD CURRENT SENSOR
200 ADJUSTMENT CIRCUIT

1. A current sensor, comprising:
at least three magnetic field detection elements configured to detect a magnetic field generated by a current flowing in a busbar; and
a current detection circuit configured to output, based on detection signals provided by the at least three magnetic field detection elements and that are related to the detected magnetic field, a detection signal of the current flowing in the busbar,
wherein the at least three magnetic field detection elements are disposed at positions different in distance in one direction with respect to the busbar,
wherein each of the at least three magnetic field detection elements is further configured to detect a magnetic field generated from a plurality of external magnetic field sources, and
wherein the current detection circuit is further configured to:
perform, based on the detection signals provided by the at least three magnetic field detection elements, a correction for canceling the magnetic field generated from the plurality of external magnetic field sources for the detection signals of the detected magnetic field, and
output a corrected detection signal as the detection signal of the current flowing in the busbar.

2. The current sensor according to claim 1, wherein the plurality of external magnetic field sources are different than the busbar.

3. The current sensor according to claim 1, wherein the current detection circuit is configured to determine, based on a difference in output of the detection signals of the magnetic field outputted from the at least three magnetic field detection elements, a magnitude of the respective magnetic field generated from the plurality of external magnetic field sources.

4. The current sensor according to claim 1, wherein the current detection circuit is configured to perform the correction for canceling the magnetic field generated from the plurality of external magnetic field sources by subtracting a value according to the determined magnitude of the magnetic field from a signal value of the one of the detection signals of the magnetic field.

5. The current sensor according to claim 1, wherein the current detection circuit is configured to perform the correction for canceling the magnetic field generated from the plurality of external magnetic field sources by an analog circuit.

6. The current sensor according to claim 5, further comprising an adjustment circuit configured to adjust a parameter of a circuit element included in the analog circuit.

7. The current sensor according to claim 1, wherein the at least three magnetic field detection elements include a first magnetic field detection element, a second magnetic field detection element, and a third magnetic field detection element.

8. The current sensor according to claim 7, wherein the current detection circuit includes:
a first amplifier configured to amplify a detection signal of the first magnetic field detection element,
a second amplifier configured to amplify a detection signal of the second magnetic field detection element,
a third amplifier configured to amplify a detection signal of the third magnetic field detection element,
a fourth amplifier configured to amplify a difference between an output signal of the second amplifier and an output signal of the third amplifier,
a fifth amplifier configured to amplify a difference between an output signal of the first amplifier and the output signal of the third amplifier,
a sixth amplifier configured to amplify an output signal of the fifth amplifier, and
a seventh amplifier configured to amplify a difference between an output signal of the fourth amplifier and an output signal of the sixth amplifier.

9. The current sensor according to claim 8, wherein the first, second, third, fourth and fifth amplifiers are configured to perform the correction for canceling the magnetic field generated from a first external magnetic field source of the plurality of external magnetic field sources.

10. The current sensor according to claim 9, wherein the sixth amplifier and the seventh amplifier are configured to perform the correction for canceling a magnetic field generated from a second external magnetic field source of the plurality of external magnetic field sources.

11. The current sensor according to claim 1, further comprising an external magnetic field detection circuit configured to perform, based on the detection signals provided by the at least three magnetic field detection elements, a correction for canceling a magnetic field generated from one of the plurality of external magnetic field sources and the magnetic field generated from the busbar for the one of the detection signals of the magnetic field.

12. The current sensor according to claim 11, wherein the external magnetic field detection circuit is further configured to output the corrected detection signal as a detection signal of a magnetic field generated from another one of the plurality of external magnetic field sources.

13. The current sensor according to claim 12, wherein the external magnetic field detection circuit is further configured to determine, based on difference in output of the detection signals of the magnetic field provided by the at least three magnetic field detection elements, a magnitude of the magnetic field generated from the one of the external magnetic field sources and the magnetic field generated from the busbar, and to perform the correction for canceling the magnetic field generated from the one external magnetic field source and the magnetic field generated from the busbar by subtracting values according to the determined magnitude of the magnetic fields from a signal value of the one detection signal of the magnetic field.

14. The current sensor according to claim 13, wherein the external magnetic field detection circuit is configured to perform the correction for canceling the magnetic field generated from the one external magnetic field source and the magnetic field generated from the busbar by an analog circuit.

15. The current sensor according to claim 14, further comprising an adjustment circuit configured to adjust a parameter of a circuit element included in the analog circuit.

16. The current sensor according to claim 7, wherein the busbar comprises a plurality of busbars each having a length that extend in a first direction.

17. The current sensor according to claim 16, wherein the first magnetic field detection element, the second magnetic field detection element, and the third magnetic field detection element overlap a center portion of one busbar of the plurality of busbars in a second direction that is orthogonal to the first direction.

18. The current sensor according to claim 16, wherein the first magnetic field detection element, the second magnetic field detection element, and the third magnetic field detection element have different heights from each other in terms of a distance from the one busbar in the second direction.

19. The current sensor according to claim 6, wherein the parameter is a gain of the circuit element included in the analog circuit.

20. The current sensor according to claim 15, wherein the parameter is a gain of the circuit element included in the analog circuit.
